(19) United States
(12) Patent Application Publication
(10) Pub. No.: US 2022/0221517 A1
(43) Pub. Date: Jul. 14, 2022

(54) HIGH-PRECISION BATTERY MODEL PARAMETER IDENTIFICATION METHOD AND SYSTEM BASED ON OUTPUT RESPONSE RECONSTRUCTION

(71) Applicant: SHANDONG UNIVERSITY, SHANDONG (CN)

(72) Inventors: Chenghui ZHANG, SHANDONG (CN); Fazheng WEN, SHANDONG (CN); Bin DUAN, SHANDONG (CN); Rui ZHU, SHANDONG (CN); Junming ZHANG, SHANDONG (CN)

(73) Assignee: SHANDONG UNIVERSITY, SHANDONG (CN)

(21) Appl. No.: 17/614,547

(22) PCT Filed: May 28, 2020
(86) PCT No.: PCT/CN2020/092937

§ 371 Date: Nov. 28, 2021

(30) Foreign Application Priority Data
May 28, 2019 (CN) 201910452182.9

(51) Int. Cl. G01R 31/367; G01R 31/385

(52) U.S. Cl. CPC G01R 31/367; G01R 31/385

(57) ABSTRACT

The present invention discloses a high-precision battery model parameter identification method and system based on output response reconstruction. The method includes: determining a pulse function based on a relationship between a measured voltage signal and a true voltage signal and a relationship between the true voltage signal and a current excitation signal; reconstructing a voltage signal based on the pulse function and the current excitation signal; and obtaining equivalent circuit model parameters of a battery based on the reconstructed voltage signal and the current excitation signal. The present invention has the following beneficial effects: the reconstructed output signal has good authenticity, and the precision of parameter identification is high. Since a complex tuning process of the filter is removed, a parameter identification process is more concise and clearer.

### BACKGROUND

### Technical Field

The present invention belongs to the technical field of identification of battery model parameters, and in particular to a high-precision battery model parameter identification method and system based on output response reconstruction.

### Description of Related Art

The description in this section merely provides background information related to the present invention and does not necessarily constitute the prior art.

As a main power source and a core component of electric vehicles, lithium-ion batteries have become a hot application and research focus due to unique advantages in energy density, power density, cycle life, service life, self-discharge rate and the like. In order to ensure safe, reliable and efficient operation of power batteries, a vehicle-mounted battery management system (BMS) needs to be used to accurately estimate and predict various states of the batteries, such as state of charge (SOC), state of health (SOH), state of power (SOP) and state of energy (SOE). However, these internal states cannot be directly obtained by using external measurement methods and need to be indirectly estimated, and a battery model is often used as a basis for estimating the states of the batteries. An equivalent circuit model is widely used due to advantages such as simple structure, low calculation amount, and easy engineering realization. An excitation signal needs to be applied to a battery to obtain an excitation response, so that model parameters are obtained through identification based on an input signal, an output signal and battery parameter identification algorithms such as a least square method, and thus various states of the battery are further estimated or predicated. Therefore, the precision of the input and output signals is closely related to the accuracy of identification of the model parameters and estimation of the battery states.

However, the inventor found that due to noise interference in a signal acquisition process, the obtained input and output signals of the battery have errors, which easily leads to inaccurate battery parameter identification and inaccurate battery state estimation. To solve this problem, according to a conventional method, input and output signals of a battery are filtered out. For example, a low-pass butterworth filter is used to filter out noise signals. However, this method has the problems that difficult selection of an optimal filter cut-off frequency and unsatisfactory filter performances.

### SUMMARY

In order to solve the problems mentioned above, the present invention provides a high-precision battery model parameter identification method and system based on output response reconstruction, which can effectively restore a true battery voltage response, and improve the accuracy of battery parameter identification and state estimation.

In some implementations, the following technical solutions are used:

Provided is a high-precision battery model parameter identification method based on output response reconstruction, including:

determining a pulse function based on a relationship between a measured voltage signal and a true voltage signal and a relationship between the true voltage signal and a current excitation signal;

reconstructing a voltage signal based on the pulse function and the current excitation signal; and

obtaining equivalent circuit model parameters of a battery based on the reconstructed voltage signal and the current excitation signal.

In some other implementations, the following technical solutions are used:

Provided is a high-precision battery model parameter identification system based on output response reconstruction, including:

a module for determining a pulse function based on a relationship between a measured voltage signal and a true voltage signal and a relationship between the true voltage signal and a current excitation signal;

a module for reconstructing a voltage signal based on the pulse function and the current excitation signal; and

a module for obtaining equivalent circuit model parameters of a battery based on the reconstructed voltage signal and the current excitation signal.

In some other implementations, the following technical solutions are used:

Provided is a terminal device includes a processor and a computer-readable storage medium. The processor is used to implement each instruction; the computer-readable storage medium is used to store a plurality of instructions, and the instructions are suitable for being loaded by a processor and executing the high-precision battery model parameter identification method based on output response reconstruction above.

In some other implementations, the following technical solutions are used:

Provided is a computer-readable storage medium, with a plurality of instructions stored therein. The instructions are suitable for being loaded by a processor of a terminal device and executing the high-precision battery model parameter identification method based on output response reconstruction above.

Compared with the prior art, the present invention has the following beneficial effects:

(1) The reconstructed output signal has good authenticity, and the parameters have high identification precision.

In the process of reconstructing a voltage of the battery, mathematical methods such as a convolution principle and calculation of correlation functions are used, a pulse function between a current excitation and the true voltage signal is obtained by using mathematical theory analysis, and a voltage response of the battery is obtained through convolution on the pulse function and the current excitation. This voltage response is very close to the true voltage signal, so that the precision of the identified model parameters of the battery is higher.

(2) The realizability is good, and the practical value is high.

The reconstructed voltage is calculated based on mathematical theory analysis, and the process of selecting a filter cut-off frequency is not involved, so that the problem of selection of an optimal cut-off frequency of a butterworth filter and the like is avoided. Since a parameter selection process is removed, a parameter identification process is more concise and clearer.

### DESCRIPTION OF THE EMBODIMENTS

It should be noted that the following detailed descriptions are all exemplary and are intended to provide further descriptions of this application. Unless otherwise specified, all technical and scientific terms used in the present invention have the same meaning as commonly understood by a person of ordinary skill in the art to which this application belongs.

It should be noted that terms used herein are only for describing specific implementations and are not intended to limit exemplary implementations according to this application. As used herein, the singular form is intended to include the plural form, unless the context clearly indicates otherwise. In addition, it should be further understood that terms “include” and/or “comprise” used in this specification indicate that there are features, steps, operations, devices, assemblies, and/or combinations thereof.

### Embodiment 1

In one or more embodiments, a high-precision battery model parameter identification method based on output response reconstruction is disclosed and includes the following steps:

(1) A pulse function is determined based on a relationship between a measured voltage signal and a true voltage signal and a relationship between the true voltage signal and a current excitation signal;

A specific implementation procedure is as follows:

1) A relationship between a voltage response and a current excitation of a battery is obtained based on a convolution principle.

If the battery stays in a stable state, a relationship between the current excitation I(k) and an output voltage U(k) is shown in a formula (1):

$$U ( k ) = {\sum }_{m = 0}^{∞} g ( k - m ) I ( m ) = {\sum }_{m = 0}^{∞} g ( m ) I ( k - m ) . \qquad ( 1 )$$

Since there is noise in the actually measured voltage signal, the pulse function ĝ and the current excitation signal I are used to reconstruct a voltage signal Û, and parameters are identified based on the voltage signal Û and the current signal I. The precision of the reconstructed voltage signal Û is greatly improved than that of the measured voltage signal, so that the accuracy of parameter identification is guaranteed.

2) The pulse function ĝ is obtained based on correlation functions.

Assuming that a relationship among the measured voltage signal Uₘₑₐₛᵤᵣₑ(k), the true voltage signal Uₜᵣᵤₑ(k) and a noise signal Vₙₒᵢₛₑ(k) is shown in a formula (2):

$${U}_{measure} ( k ) = {U}_{true} ( k ) + {V}_{n o i s e} ( k ) \qquad ( 2 )$$

and a relationship between Uₜᵣᵤₑ and the current excitation I is shown in the formula (1), a correlation function between Uₘₑₐₛᵤᵣₑ(k) and I(k) is:

$$\begin{matrix}{R}_{U I} ( λ ) = E \{ I ( k - λ ) {U}_{measure} ( k ) \} , & ( 3 ) \\ {R}_{UI} ( λ ) = E \{ I ( k - λ ) ( {\sum }_{m = 0}^{∞} \hat{g} ( m ) I ( k - m ) + {V}_{n o i s e} ) \} , and & ( 4 ) \\ {R}_{UI} = {\sum }_{m = 0}^{∞} \hat{g} ( m ) {R}_{II} ( λ - m ) + E \{ I ( k - λ ) {V}_{noise} \} . & ( 5 )\end{matrix}$$

Since the current excitation signal I is not related to the voltage noise signal Vₙₒᵢₛₑ,

$$E \{ I ( k - λ ) {V}_{n o i s e} \} = 0 ; \qquad ( 6 )$$

then a formula (7) can be obtained

$${R}_{UI} ( λ ) = {\sum }_{m = 0}^{∞} \hat{g} ( m ) {R}_{II} ( λ - m ) , \qquad ( 7 )$$

Rewriting the formula (7) into a matrix form, it gets

$$( \begin{matrix}{R}_{UI} ( 0 ) \\ {R}_{UI} ( 1 ) \\ \cdot \\ \cdot \\ \cdot \\ \cdot \\ {R}_{UI} ( N - 1 )\end{matrix} ) = ( \begin{matrix}{R}_{II} ( 0 ) & {R}_{II} ( - 1 ) & … & {R}_{II} ( - N + 1 ) \\ {R}_{II} ( 1 ) & {R}_{II} ( 0 ) & … & {R}_{II} ( - N + 2 ) \\ \cdot & & \cdot & \\ \cdot & & \cdot & \\ \cdot & & \cdot & \\ \cdot & & \cdot & \\ {R}_{II} ( N - 1 ) & {R}_{II} ( N - 2 ) & … & {R}_{II} ( 0 )\end{matrix} ) \times ( \begin{matrix}\hat{g} ( 0 ) \\ \hat{g} ( 1 ) \\ \cdot \\ \cdot \\ \cdot \\ \cdot \\ \hat{g} ( N - 1 )\end{matrix} ) , \qquad ( 8 )$$

A pseudo-random sequence signal is used as the battery excitation signal, and an autocorrelation function thereof is

$$\begin{matrix}{R}_{II} ( λ ) = \{ \begin{matrix}{a}^{2} & λ = 0 \\ - \frac{{a}^{2}}{N} & 1 \leq λ \leq N - 1\end{matrix} , \\ Let & ( 9 ) \\ φ = ( \begin{matrix}{R}_{II} ( 0 ) & {R}_{II} ( - 1 ) & … & {R}_{II} ( - N + 1 ) \\ {R}_{II} ( 1 ) & {R}_{II} ( 0 ) & … & {R}_{II} ( - N + 2 ) \\ \cdot & & & \cdot \\ \cdot & & & \cdot \\ \cdot & & & \cdot \\ \cdot & & & \cdot \\ {R}_{II} ( N - 1 ) & {R}_{II} ( N - 2 ) & … & {R}_{II} ( 0 )\end{matrix} ) , \\ then & ( 10 ) \\ \hat{g} = {φ}^{- 1} {R}_{UI} ; \\ further & ( 11 ) \\ {R}_{UI} ( λ ) = \frac{1}{N} {\sum }_{m = 0}^{N - 1} {U}_{m e a s u r e} ( m ) I ( m - λ ) . & ( 12 )\end{matrix}$$

The pulse function ĝ is obtained by substituting the formulas (9), (10) and (12) into the formula (11).

(2) The voltage signal is reconstructed based on the pulse function and the current excitation signal.

Convolution operation is performed on the obtained pulse function ĝ and the current excitation Ito obtain a reconstructed voltage Û, and the precision of the voltage is much higher than that of a voltage obtained after filtering with a general low-pass filter. This process can be implemented by a person of ordinary skill in the art according to the prior art and is not described in detail.

(3) Equivalent circuit model parameters of the battery are obtained based on the reconstructed voltage signal and the current excitation signal.

Equivalent circuit model parameters with high precision of the battery can be obtained by using a recursive least square (RLS) algorithm based on the reconstructed voltage Û and the current excitation I. This process can be implemented by a person of ordinary skill in the art according to the prior art and is not described in detail.

### Embodiment 2

In one or more embodiments, disclosed is a high-precision battery model parameter identification system based on output response reconstruction, including:

a module for determining a pulse function based on a relationship between a measured voltage signal and a true voltage signal and a relationship between the true voltage signal and a current excitation signal;

a module for reconstructing a voltage signal based on the pulse function and the current excitation signal; and

a module for obtaining equivalent circuit model parameters of a battery based on the reconstructed voltage signal and the current excitation signal.

### Embodiment 3

In one or more embodiments, disclosed is a terminal device, including a server, the server includes a memory, a processor and a computer program which is stored on the memory and can run on the processor. The high-precision battery model parameter identification method based on output response reconstruction in Example 1 is implemented when the processor executes the program. For brevity, details are not described herein again.

It should be understood that in this embodiment, the processor may be a central processing unit (CPU); or the processor may be another general purpose processor, a digital signal processor (DSP), an application-specific integrated circuit (ASIC), a field programmable gate array (FPGA) or another programmable logical device, a discrete gate or a transistor logical device, a discrete hardware component, or the like. The general-purpose processor may be a microprocessor, or the processor may be any conventional processor and the like.

The memory may include a read-only memory and a random-access memory, and provide an instruction and data to the processor. A part of the memory may further include a non-volatile random-access memory. For example, the memory may further store information about a device type.

During implementation, the steps of the foregoing method may be completed through an integrated logic circuit of hardware or an instruction in the form of software in the processor.

The steps of the methods disclosed with reference to Embodiment 1 may be directly embodied as being implemented by a hardware processor or by a combination of hardware and software modules in a processor. The software module may be located in a mature storage medium in the field such as a random access memory, a flash memory, a read-only memory, a programmable read-only memory, an electrically erasable programmable memory, or a register. The storage medium is located in the memory. The processor reads information in the memory and uses hardware thereof to implement the steps of the foregoing methods. To avoid repetition, details are not described herein again.

A person of ordinary skill in the art may notice that the exemplary units and algorithm steps described with reference to this embodiment can be implemented in electronic hardware, or a combination of computer software and electronic hardware. Whether to execute the functions in hardware or software mode depends on particular applications and design constraint conditions of the technical solutions. A person skilled in the art may use different methods to implement the described functions for each particular application, but it is not to be considered that the implementation goes beyond the scope of this application.

The specific implementations of the present invention are described above, but are not intended to limit the protection scope of the present invention. A person skilled in the art should understand that various modifications or deformations may be made without creative efforts based on the technical solutions of the present invention, and such modifications or deformations shall fall within the protection scope of the present invention.

1. A high-precision battery model parameter identification method based on output response reconstruction, comprising:
determining a pulse function based on a relationship between a measured voltage signal and a true voltage signal and a relationship between the true voltage signal and a current excitation signal;
reconstructing a voltage signal based on the pulse function and the current excitation signal; and
obtaining equivalent circuit model parameters of a battery based on the reconstructed voltage signal and the current excitation signal.

2. The high-precision battery model parameter identification method based on output response reconstruction according to claim 1, wherein the relationship between the measured voltage signal and the true voltage signal is specifically:
$${U}_{m e a s u r e} ( k ) = {U}_{t r u e} ( k ) + {V}_{n o i s e} ( k )$$
where Uₘₑₐₛᵤᵣₑ(k) is the measured voltage signal, Uₜᵣᵤₑ(k) is the true voltage signal, and Vₙₒᵢₛₑ(k) is a noise signal.

3. The high-precision battery model parameter identification method based on output response reconstruction according to claim 1, wherein the relationship between the true voltage signal and the current excitation signal is specifically:
$${U}_{true} ( k ) = {\sum }_{m = 0}^{∞} g ( m ) I ( k - m )$$
where Uₜᵣᵤₑ(k) is the true voltage signal, I(k-m) is the current excitation signal, and g(m) is the pulse function.

4. The high-precision battery model parameter identification method based on output response reconstruction according to claim 1, wherein the pulse function is specifically:
$$\hat{g} = {φ}^{- 1} {R}_{UI} \\ φ = ( \begin{matrix}{R}_{II} ( 0 ) & {R}_{II} ( - 1 ) & … & {R}_{II} ( - N + 1 ) \\ {R}_{II} ( 1 ) & {R}_{II} ( 0 ) & … & {R}_{II} ( - N + 2 ) \\ \cdot & & & \cdot \\ \cdot & & & \cdot \\ \cdot & & & \cdot \\ \cdot & & & \cdot \\ {R}_{II} ( N - 1 ) & {R}_{II} ( N - 2 ) & … & {R}_{II} ( 0 )\end{matrix} ) , \\ {R}_{II} ( λ ) = \{ \begin{matrix}{a}^{2} & λ = 0 \\ - \frac{{a}^{2}}{N} & 1 \leq λ \leq N - 1\end{matrix} , \qquad ( 1 )$$
α is an amplitude of the excitation current signal, N is a quantity of sampling points, and Ru(λ) is an even function; therefore, when λ is a negative number, a value of Ru(λ) is consistent with the value when λ is positive;
$${R}_{UI} ( λ ) = \frac{1}{N} {\sum }_{m = 0}^{N - 1} {U}_{m e a s u r e} ( m ) I ( m - λ ) .$$

5. The high-precision battery model parameter identification method based on output response reconstruction according to claim 1, wherein convolution operation is performed on the obtained pulse function and the current excitation signal to reconstruct a voltage signal.

6. A high-precision battery model parameter identification system based on output response reconstruction, comprising:
a module for determining a pulse function based on a relationship between a measured voltage signal and a true voltage signal and a relationship between the true voltage signal and a current excitation signal;
a module for reconstructing a voltage signal based on the pulse function and the current excitation signal; and
a module for obtaining equivalent circuit model parameters of a battery based on the reconstructed voltage signal and the current excitation signal.

7. A terminal device, comprising a processor and a computer-readable storage medium, wherein the processor is used to implement each instruction; the computer-readable storage medium is used to store a plurality of instructions, and the instructions are suitable for being loaded by the processor and executing the high-precision battery model parameter identification method based on output response reconstruction according to claim 1.

8. A computer-readable storage medium, with a plurality of instructions stored therein, wherein the instructions are suitable for being loaded by a processor of a terminal device and executing the high-precision battery model parameter identification method based on output response reconstruction according to claim 1.

9. A terminal device, comprising a processor and a computer-readable storage medium, wherein the processor is used to implement each instruction;
the computer-readable storage medium is used to store a plurality of instructions, and the instructions are suitable for being loaded by the processor and executing the high-precision battery model parameter identification method based on output response reconstruction according to claim 2.

10. A terminal device, comprising a processor and a computer-readable storage medium, wherein the processor is used to implement each instruction;
the computer-readable storage medium is used to store a plurality of instructions, and the instructions are suitable for being loaded by the processor and executing the high-precision battery model parameter identification method based on output response reconstruction according to claim 3.

11. A terminal device, comprising a processor and a computer-readable storage medium, wherein the processor is used to implement each instruction;
the computer-readable storage medium is used to store a plurality of instructions, and the instructions are suitable for being loaded by the processor and executing the high-precision battery model parameter identification method based on output response reconstruction according to claim 4.

12. A terminal device, comprising a processor and a computer-readable storage medium, wherein the processor is used to implement each instruction;
the computer-readable storage medium is used to store a plurality of instructions, and the instructions are suitable for being loaded by the processor and executing the high-precision battery model parameter identification method based on output response reconstruction according to claim 5.

13. A computer-readable storage medium, with a plurality of instructions stored therein, wherein the instructions are suitable for being loaded by a processor of a terminal device and executing the high-precision battery model parameter identification method based on output response reconstruction according to claim 2.

14. A computer-readable storage medium, with a plurality of instructions stored therein, wherein the instructions are suitable for being loaded by a processor of a terminal device and executing the high-precision battery model parameter identification method based on output response reconstruction according to claim 3.

15. A computer-readable storage medium, with a plurality of instructions stored therein, wherein the instructions are suitable for being loaded by a processor of a terminal device and executing the high-precision battery model parameter identification method based on output response reconstruction according to claim 4.

16. A computer-readable storage medium, with a plurality of instructions stored therein, wherein the instructions are suitable for being loaded by a processor of a terminal device and executing the high-precision battery model parameter identification method based on output response reconstruction according to claim 5.
